(19) United States
(12) Patent Application Publication
(10) Pub. No.: US 2024/0345953 A1
(43) Pub. Date: Oct. 17, 2024

(54) Content-Addressable Memory based Nondeterministic Finite Automata Accelerator

(71) Applicants: Wijdaan Masud Rizavi, Watford (GB); Robert Critchlow, Marlow (GB); Arpad Kiss, Burton-on-Trent (GB); Frederic Richard, Maidenhead (GB)

(72) Inventors: Wijdaan Masud Rizavi, Watford (GB); Robert Critchlow, Marlow (GB); Arpad Kiss, Burton-on-Trent (GB); Frederic Richard, Maidenhead (GB)

(21) Appl. No.: 18/756,368

(22) Filed: Jun. 27, 2024

(51) Int. Cl. G06F 12/06

(52) U.S. Cl. CPC G06F 12/0653

(57) ABSTRACT

Systems and methods are provided for using TCAM tables in an NFA accelerator to achieve high throughput regular expression matching, improved scalability, improved resource utilization, and runtime and compile time reconfigurability, while remaining easy-to-deploy (no reliance on specialized hardware) thereby reducing customer barrier-to-entry. The architecture is programmable at runtime due to its dependency on TCAM for its configuration data. Moreover, FPGA gates may be used in the NFA accelerator and may be replaced at runtime using partial reconfiguration to allow limitations in the number of indirection tables and the capacities of the TCAMs to be adjusted at runtime.

### BACKGROUND

The present disclosure relates generally to nondeterministic finite automata (NFA) accelerators, and more specifically to implementing content-addressable memory (CAM) in the NFA accelerators.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

High-throughput, real-time search functions may be important to many applications in networking, cybersecurity, and web services, etc. Regular expressions are patterns in strings that regular expression engines/processors use for text processing using pattern matching. With the exponential growth of data volume and complexity, hardware acceleration has become increasingly important for efficient regular expression matching.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device, in accordance with an embodiment of the present disclosure;

FIG. 2 is a block diagram of the integrated circuit device of FIG. 1, in accordance with an embodiment of the present disclosure;

FIG. 3 is a block diagram of programmable fabric of the integrated circuit device of FIG. 1, in accordance with an embodiment of the present disclosure;

FIG. 4 is a block diagram illustrating various embodiments of NFAs for a regular expression, in accordance with aspects of the present disclosure;

FIG. 5 is a flow diagram for a process to use ternary content-addressable memory (TCAM) in an embodiment of a NFA accelerator core to search a regular expression in input data, in accordance with aspects of the present disclosure;

FIG. 6 is a flow diagram for a process to use TCAM in another embodiment of a NFA accelerator core to search a regular expression in input data, in accordance with aspects of the present disclosure;

FIG. 7 is a block diagram showing an implementation of a regular expression engine that may use the NFA accelerator core of FIG. 5 or FIG. 6 to search a regular expression in input data, in accordance with aspects of the present disclosure;

FIG. 8 is a flow chart showing a method for matching a regular expression using the regular expression engine of FIG. 7, in accordance with an embodiment of the present disclosure; and

FIG. 9 is a block diagram of a data processing system including the integrated circuit device of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As previously noted, high-throughput, real-time search functions may be important to many applications in networking, cybersecurity, and web services, etc. Regular expressions may be used to describe patterns in strings for text processing and pattern matching. Regular expressions are composed of literal characters and/or special metacharacters that define matching rules. For example, the regular expression “Pen*e” represents the pattern where “Pe” is followed by any number (e.g., 0, 1, 2, 3 . . . ) of “n” characters, followed by “e”. Regular expressions may be used for parsing text files for specific patterns, verifying test results, and finding keywords in emails or webpages. Regular expressions may be converted into equivalent Nondeterministic Finite Automatons (NFAs). For example, the Kleene's theorem or other suitable algorithms may be used to transform between a given NFA and a regular expression. NFAs are state machines with a finite number of states and transitions between those states based on input symbols. NFAs may be non-deterministic, meaning that for a given state and input symbol, there may be multiple possible transitions. Automata perform searches with time complexity independent of input text content by concurrently investigating paths and maintaining state information thereby eliminating the need to backtrack across match possibilities. These algorithms may be efficiently realized on various accelerator platforms (e.g., GPUS, FPGAs, custom automata hardware). With the exponential growth of data volume and complexity, hardware acceleration has become increasingly important for efficient regular expression matching. Accordingly, it is desirable to develop high throughput NFA implementations suitable for Infrastructure Processing Units (IPUs), inline, and/or storage-based acceleration that offer reconfigurability and scalability.

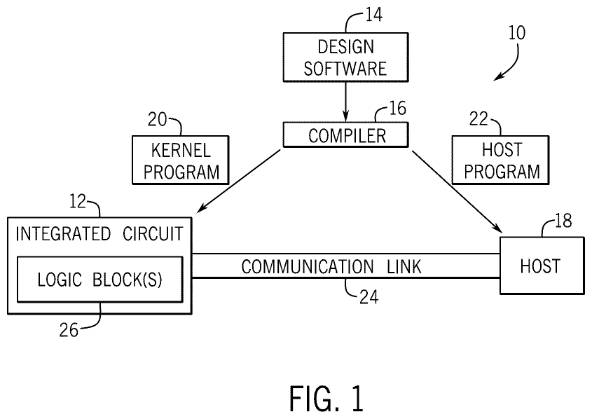

With the foregoing in mind, FIG. 1 illustrates a block diagram of a system 10 that may implement one or more functionalities. For example, a designer may desire to implement functionality, such as the operations of this disclosure, on an integrated circuit device 12 (e.g., a programmable logic device, such as a field programmable gate array (FPGA) or an application specific integrated circuit (ASIC)). In some cases, the designer may specify a high-level program to be implemented, such as an OpenCL® program or SYCL®, which may enable the designer to more efficiently and easily provide programming instructions to configure a set of programmable logic cells for the integrated circuit device 12 without specific knowledge of low-level hardware description languages (e.g., Verilog or VHDL). For example, since OpenCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

The designer may implement high-level designs using design software 14, such as a version of INTEL® QUARTUS® by INTEL CORPORATION. The design software 14 may use a compiler 16 to convert the high-level program into a lower-level description. In some embodiments, the compiler 16 and the design software 14 may be packaged into a single software application. The compiler 16 may provide machine-readable instructions representative of the high-level program to a host 18 and the integrated circuit device 12. The host 18 may receive a host program 22 which may be implemented by the kernel programs 20. To implement the host program 22, the host 18 may communicate instructions from the host program 22 to the integrated circuit device 12 via a communications link 24, which may be, for example, direct memory access (DMA) communications or peripheral component interconnect express (PCIe) communications. In some embodiments, the kernel programs 20 and the host 18 may enable configuration of one or more logic circuitry 26 on the integrated circuit device 12. The logic circuitry 26 may include circuitry and/or other logic elements and may be configured to implement arithmetic operations, such as addition and multiplication.

The designer may use the design software 14 to generate and/or to specify a low-level program, such as the low-level hardware description languages described above. For example, the design software 14 may be used to map a workload to one or more routing resources of the integrated circuit device 12 based on a timing, a wire usage, a logic utilization, and/or a routability. Additionally or alternatively, the design software 14 may be used to route first data to a portion of the integrated circuit device 12 and route second data, power, and clock signals to a second portion of the integrated circuit device 12. Further, in some embodiments, the system 10 may be implemented without a host program 22 and/or without a separate host program 22. Moreover, in some embodiments, the techniques described herein may be implemented in circuitry as a non-programmable circuit design. Thus, embodiments described herein are intended to be illustrative and not limiting.

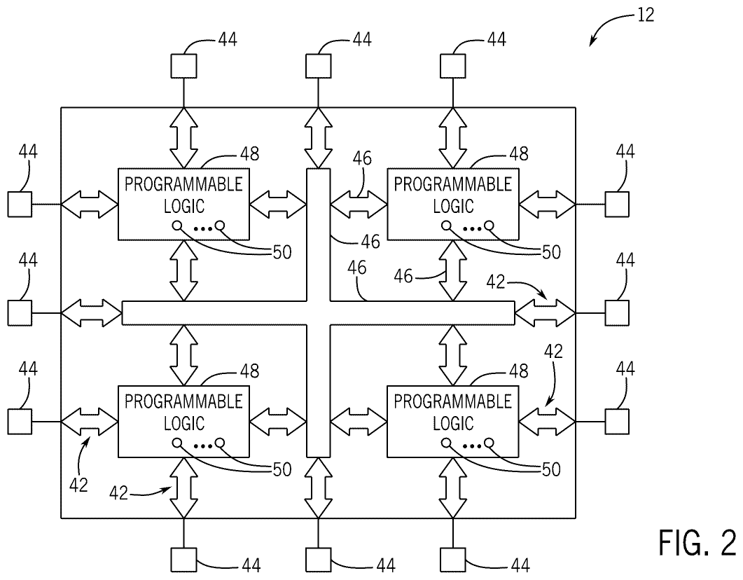

Turning now to a more detailed discussion of the integrated circuit device 12, FIG. 2 is a block diagram of an example of the integrated circuit device 12 as a programmable logic device, such as a field-programmable gate array (FPGA). Further, it should be understood that the integrated circuit device 12 may be any other suitable type of programmable logic device (e.g., a structured ASIC such as eASIC™ by Intel Corporation and/or application-specific standard product). The integrated circuit device 12 may have input/output circuitry 42 for driving signals off the device and for receiving signals from other devices via input/output pins 44. Interconnection resources 46, such as global and local vertical and horizontal conductive lines and buses, and/or configuration resources (e.g., hardwired couplings, logical couplings not implemented by designer logic), may be used to route signals on integrated circuit device 12. Additionally, interconnection resources 46 may include fixed interconnects (conductive lines) and programmable interconnects (i.e., programmable connections between respective fixed interconnects). For example, the interconnection resources 46 may be used to route signals, such as clock or data signals, through the integrated circuit device 12. Additionally or alternatively, the interconnection resources 46 may be used to route power (e.g., voltage) through the integrated circuit device 12. Programmable logic 48 may include combinational and sequential logic circuitry. For example, programmable logic 48 may include look-up tables, registers, and multiplexers. In various embodiments, the programmable logic 48 may be configured to perform a custom logic function. The programmable interconnects associated with interconnection resources may be considered to be a part of programmable logic 48.

Programmable logic devices, such as the integrated circuit device 12, may include programmable elements 50 with the programmable logic 48. In some embodiments, at least some of the programmable elements 50 may be grouped into logic array blocks (LABs). As discussed above, a designer (e.g., a user, a customer) may (re)program (e.g., (re)configure) the programmable logic 48 to perform one or more desired functions. By way of example, some programmable logic devices may be programmed or reprogrammed by configuring programmable elements 50 using mask programming arrangements, which is performed during semiconductor manufacturing. Other programmable logic devices are configured after semiconductor fabrication operations have been completed, such as by using electrical programming or laser programming to program the programmable elements 50. In general, programmable elements 50 may be based on any suitable programmable technology, such as fuses, anti-fuses, electrically programmable read-only-memory technology, random-access memory cells, mask-programmed elements, and so forth.

Many programmable logic devices are electrically programmed. With electrical programming arrangements, the programmable elements 50 may be formed from one or more memory cells. For example, during programming, configuration data is loaded into the memory cells using input/output pins 44 and input/output circuitry 42. In one embodiment, the memory cells may be implemented as random-access-memory (RAM) cells. The use of memory cells based on RAM technology as described herein is intended to be only one example. Further, since these RAM cells are loaded with configuration data during programming, they are sometimes referred to as configuration RAM cells (CRAM). These memory cells may each provide a corresponding static control output signal that controls the state of an associated logic component in programmable logic 48. In some embodiments, the output signals may be applied to the gates of metal-oxide-semiconductor (MOS) transistors within the programmable logic 48.

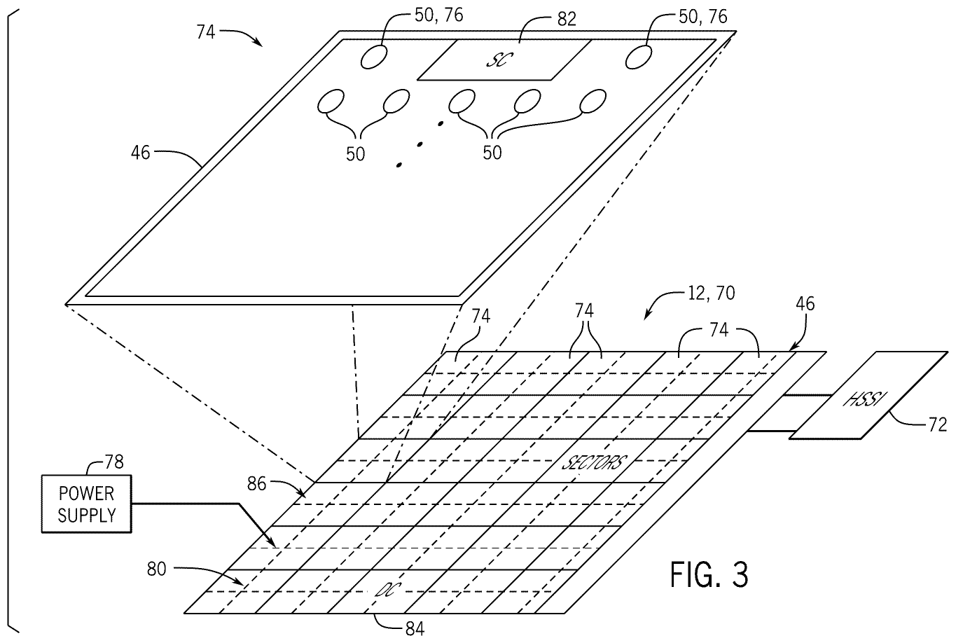

The integrated circuit device 12 may include any programmable logic device such as a field programmable gate array (FPGA) 70, as shown in FIG. 3. For the purposes of this example, the FPGA 70 is referred to as a FPGA, though it should be understood that the device may be any suitable type of programmable logic device (e.g., an application-specific integrated circuit and/or application-specific standard product). In one example, the FPGA 70 is a sectorized FPGA of the type described in U.S. Pat. No. 10,523,207, “Programmable Circuit Having Multiple Sectors,” which is incorporated by reference in its entirety for all purposes. The FPGA 70 may be formed on a single plane. Additionally or alternatively, the FPGA 70 may be a three-dimensional FPGA having a base die and a fabric die of the type described in U.S. Pat. No. 10,833,679, “Multi-Purpose Interface for Configuration Data and Designer Fabric Data,” which is incorporated by reference in its entirety for all purposes.

In the example of FIG. 3, the FPGA 70 may include transceiver 72 that may include and/or use input/output circuitry, such as input/output circuitry 42 in FIG. 2, for driving signals off the FPGA 70 and for receiving signals from other devices. Interconnection resources 46 may be used to route signals, such as clock or data signals, through the FPGA 70. The FPGA 70 is sectorized, meaning that programmable logic resources may be distributed through a number of discrete programmable logic sectors 74. Programmable logic sectors 74 may include a number of programmable elements 50 having operations defined by configuration memory 76 (e.g., CRAM). A power supply 78 may provide a source of voltage (e.g., supply voltage) and current to a power distribution network (PDN) 80 that distributes electrical power to the various components of the FPGA 70. Operating the circuitry of the FPGA 70 causes power to be drawn from the power distribution network 80.

There may be any suitable number of programmable logic sectors 74 on the FPGA 70. Indeed, while 29 programmable logic sectors 74 are shown here, it should be appreciated that more or fewer may appear in an actual implementation (e.g., in some cases, on the order of 50, 100, 500, 1000, 5000, 10,000, 50,000 or 100,000 sectors or more). Programmable logic sectors 74 may include a sector controller (SC) 82 that controls operation of the programmable logic sectors 74. Sector controllers 82 may be in communication with a device controller (DC) 84.

Sector controllers 82 may accept commands and data from the device controller 84 and may read data from and write data into its configuration memory 76 based on control signals from the device controller 84. In addition to these operations, the sector controller 82 may be augmented with numerous additional capabilities. For example, such capabilities may include locally sequencing reads and writes to implement error detection and correction on the configuration memory 76 and sequencing test control signals to effect various test modes.

The sector controllers 82 and the device controller 84 may be implemented as state machines and/or processors. For example, operations of the sector controllers 82 or the device controller 84 may be implemented as a separate routine in a memory containing a control program. This control program memory may be fixed in a read-only memory (ROM) or stored in a writable memory, such as random-access memory (RAM). The ROM may have a size larger than would be used to store only one copy of each routine. This may allow routines to have multiple variants depending on “modes” the local controller may be placed into. When the control program memory is implemented as RAM, the RAM may be written with new routines to implement new operations and functionality into the programmable logic sectors 74. This may provide usable extensibility in an efficient and easily understood way. This may be useful because new commands could bring about large amounts of local activity within the sector at the expense of only a small amount of communication between the device controller 84 and the sector controllers 82.

Sector controllers 82 thus may communicate with the device controller 84, which may coordinate the operations of the sector controllers 82 and convey commands initiated from outside the FPGA 70. To support this communication, the interconnection resources 46 may act as a network between the device controller 84 and sector controllers 82. The interconnection resources 46 may support a wide variety of signals between the device controller 84 and sector controllers 82. In one example, these signals may be transmitted as communication packets.

The use of configuration memory 76 based on RAM technology as described herein is intended to be only one example. Moreover, configuration memory 76 may be distributed (e.g., as RAM cells) throughout the various programmable logic sectors 74 of the FPGA 70. The configuration memory 76 may provide a corresponding static control output signal that controls the state of an associated programmable element 50 or programmable component of the interconnection resources 46. The output signals of the configuration memory 76 may be applied to the gates of metal-oxide-semiconductor (MOS) transistors that control the states of the programmable elements 50 or programmable components of the interconnection resources 46.

The programmable elements 50 of the FPGA 40 may also include some signal metals (e.g., communication wires) to transfer a signal. In an embodiment, the programmable logic sectors 74 may be provided in the form of vertical routing channels (e.g., interconnects formed along a y-axis of the FPGA 70) and horizontal routing channels (e.g., interconnects formed along an x-axis of the FPGA 70), and each routing channel may include at least one track to route at least one communication wire. If desired, communication wires may be shorter than the entire length of the routing channel. That is, the communication wire may be shorter than the first die area or the second die area. A length L wire may span L routing channels. As such, a length of four wires in a horizontal routing channel may be referred to as “H4” wires, whereas a length of four wires in a vertical routing channel may be referred to as “V” wires.

As discussed above, some embodiments of the programmable logic fabric may be configured using indirect configuration techniques. For example, an external host device may communicate configuration data packets to configuration management hardware of the FPGA 70. The data packets may be communicated internally using data paths and specific firmware, which are generally customized for communicating the configuration data packets and may be based on particular host device drivers (e.g., for compatibility). Customization may further be associated with specific device tape outs, often resulting in high costs for the specific tape outs and/or reduced scalability of the FPGA 70.

High-throughput, real-time search functions may be important to many applications in networking, cybersecurity, and web services, etc. Regular expressions may be used to describe patterns in strings for text processing and pattern matching. Regular expressions are composed of literal characters and special metacharacters that define matching rules. For example, the regular expression “Pen*e” represents the pattern where “Pe” is followed by any number of “n” characters, followed by “e”. Regular expressions may be used for parsing text files for specific patterns, verifying test results, and finding keywords in emails or webpages. Regular expressions may be converted into equivalent Nondeterministic Finite Automatons (NFAs). For example, the Kleene's theorem and/or other algorithms may be used to transform between a given NFA and a regular expression. NFAs are state machines with a finite number of states and transitions between those states based on input symbols. NFAs may be non-deterministic, meaning that for a given state and input symbol, there may be multiple possible transitions. Automata perform searches with time complexity independent of input text content by concurrently investigating paths and maintaining state information thereby eliminating the need to backtrack across match possibilities. These algorithms may be efficiently realized on various accelerator platforms (e.g., GPUS, FPGAs, custom automata hardware). With the exponential growth of data volume and complexity, hardware acceleration has become increasingly important for efficient regular expression matching. Accordingly, it is desirable to develop high throughput NFA implementations suitable for Infrastructure Processing Units (IPUs), inline, and/or storage-based acceleration that offer reconfigurability and scalability.

NFAs may be encoded and stored in a content-addressable memory (CAM) to achieve high throughput. For example, the CAM may be capable of ternary matching and may include configurable memory tables, which, when combined with a processor, allows for runtime reconfigurability (e.g., at multi-100 Gbps rates). Regular expressions may be transformed to NFAs using standard algorithms on the processor thereby enabling this architecture to greatly accelerate most regular expression matching applications. Content-Addressable Memory (CAM) is a special type of memory that may be used to improve the performance of the NFA accelerator for regular expressions. In a CAM, input search data may be compared against a table of stored data, and the address of the matching data may be returned as results. The CAM may search the entire table in one operation (e.g., one clock cycle). Some CAM tables may provide only two results (e.g., false or true), and these CAM tables may be useful for searching for exact matches. Ternary CAMs (TCAMs) may allow a third matching state of “don't care” for one or more bits in the stored word, thereby providing ternary matching, which adds flexibility to the search. Accordingly, implementations described herein are directed to using a CAM (e.g., a TCAM) to achieve high throughput regular expression matching, which offers improved scalability, improved resource utilization, and runtime and compile time reconfigurability.

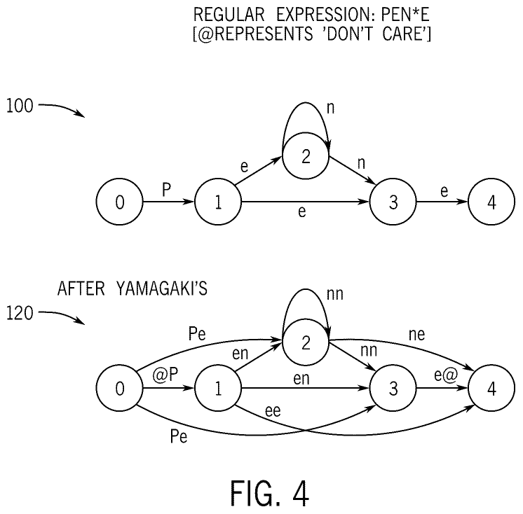

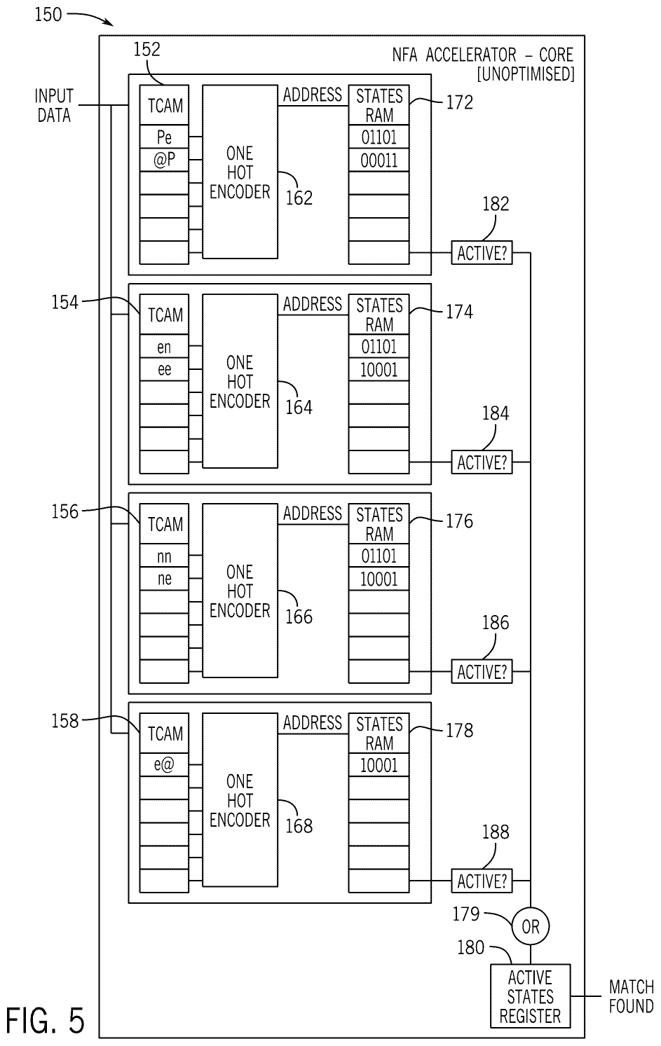

FIG. 4 includes a diagram illustrating an embodiment of a NFA 100 for a regular expression of “Pen*e” and a diagram illustrating another embodiment of a NFA 120 for the regular expression of “Pen*e”. The NFA 100 may include 5 states, among which state 0 is the starting state and state 4 is the end state. In the illustrated embodiment of NFA 100, only one character may be processed per clock cycle. For example, state 0 has one edge labelled “P”, when data streamed in is “P”, the NFA 100 transitions to state 1/state 1 may be enabled. State 1 has two edges both labelled “e”. When data streamed in is “e”, state 2 and state 3 may be enabled. State 2 has two edges both labelled “n”. When data streamed in is “n”, state 2 and state 3 may be enabled. State 3 has one edge labelled “e”. When data streamed in is “e”, state 4 may be enabled. In some embodiments, an algorithm (e.g., Yamagaki's algorithm, “High-speed regular expression matching engine using multi-character NFA,” 2008 International Conference on Field Programmable Logic and Applications, Heidelberg, Germany, 2008, pp. 131-136, doi: 10.1109/FPL.2008.4629920) may be used to construct an NFA that processes multiple characters per clock cycle. For example, the NFA 100 may be used to construct the NFA 120, which may process twice the number of characters as the NFA 100. Accordingly, in the NFA 120, two characters may be processed per clock cycle (edge-width doubling). For example, state 0 of the NFA 120 has edges labelled “Pe” and “@P”. “@” represents “don't care”, which means “@” may represent any character. When data streamed in is “@P”, state 1 may be enabled; when data streamed in is “Pe”, state 2 and state 3 may be enabled. State 1 of the NFA 120 has edges labelled “en” and “ee”. When data streamed in is “en”, state 2 and state 3 may be enabled. When data streamed in is “ee”, state 4 may be enabled. State 2 of the NFA 120 has edges labelled “nn” and “ne”. When data streamed in is “nn”, state 2 and state 3 may be enabled. When data streamed in is “ne”, state 4 may be enabled. State 3 of the NFA 120 has an edge labelled “e@”. When data streamed in is “e@”, state 4 may be enabled. Processing more than one character per clock cycle may efficiently increase the throughput of the regular expression matching. As illustrated in FIG. 4, the data streamed in the NFA 120 may be compared to all edges of a state during runtime, thus ternary content-addressable memory (TCAM) may be implemented to perform all checks simultaneously. For instance, since the NFA 120 has 4 states excluding the end state, 4 state blocks may be used to build the state table, as illustrated in FIG. 5.

FIG. 5 is a flow diagram for a process to use TCAM in an embodiment of a NFA accelerator core 150 (e.g., of the programmable logic device 10) to search a regular expression (e.g., “Pen*e”) in input data. The NFA accelerator core 150 may include 4 state blocks corresponding to 4 states excluding the end state. For instance, state 0 of the NFA 120 has edges labelled “Pe” and “@P”, and the two terms may be stored in a state block 152 (e.g., a TCAM table). State 1 of the NFA 120 has edges labelled “en” and “ee”, and the two terms may be stored in a state block 154 (e.g., a TCAM table). State 2 of the NFA 120 has edges labelled “nn” and “ne”, and the two terms may be stored in a state block 156 (e.g., a TCAM table). State 3 of the NFA 120 has an edge labelled “e@”, and the term may be stored in a state block 158 (e.g., a TCAM table). The input data may be compared against the terms stored in the state blocks of the NFA accelerator core 150, and the TCAM may search all state blocks of the NFA accelerator core 150 in one operation (e.g., one clock cycle) and provide “1” (true) or “0” (false) as the search result for each term.

Each state block may be coupled to a respective one-hot encoder for generating mapping addresses in a respective states RAM based on the search result. State vectors may be stored in the states RAM, and each bit of a state vector may represent the condition of a state. Accordingly, the matched term may be mapped to a corresponding state vector stored in the mapping address of the corresponding states RAM. For example, when a term stored in the state block is matched in the input data, a bit “1” may be returned as a result for that term and input into the one-hot encoder, while a bit “0” may be returned if a term stored in the state block is not found in the input data and input into the one-hot encoder. The output of the one-hot encoder may be a one-hot code having only one bit of “1” corresponding to the matched term. For example, the state block 152 may be coupled to a one-hot encoder 162, which may be used to generate an address (e.g., the queue index) of a states RAM 172 (e.g., an indirection table) based on search results of the terms stored in the state block 152. For example, if the term “Pe” is matched with the input data, the one-hot encoder may output “000001”, corresponding to the first entry of the states RAM 172, which stores a state vector “01101”. As illustrated in FIG. 4, at state 0, the input data being “Pe” may enable states 2 and 3, hence the corresponding state vector for “Pe” is “01101”, with bits 2 and 3 being “1” since they represent states 2 and 3, respectively. Note that bit 0 of a state vector is always high as it is the starting state of the NFA 120; accordingly, state 0 is always enabled for every clock cycle. Similarly, at state 0, the input data being “@P” may enable state 1, hence the corresponding state vector for “@P” is “00011”, with bit 1 being “1” since it represents state 1. If the term “@P” is matched with the input data, the one-hot encoder 162 may output “000010”, corresponding to the second entry of the states RAM 172, which includes a state vector “00011”. In some embodiments, more than one terms may be matched with the input data, and the one-hot encoder may apply a priority rule and output the address corresponding to the priority of the matched terms (e.g., the highest match).

Similarly, the state block 154 may be coupled to a one-hot encoder 164, which may be used to generate an address (e.g., the queue index) of a states RAM 174 (e.g., an indirection table) based on search results of the terms stored in the state block 154. The states RAM 174 may store the corresponding state vector “01101” in the first entry for the term “en”, indicating that the input data being “en” at state 1 may enable states 2 and 3. The states RAM 174 may store the corresponding state vector “10001” in the second entry for the term “ee”, indicating that the input data being “ee” at state 1 may enable state 4.

Similarly, the state block 156 may be coupled to a one-hot encoder 166, which may be used to generate an address (e.g., the queue index) of a states RAM 176 (e.g., an indirection table) based on search results of the terms stored in the state block 156. The states RAM 176 may store the corresponding state vector “01101” in the first entry for the term “nn”, indicating that the input data being “nn” at state 2 may enable states 2 and 3. The states RAM 176 may store the corresponding state vector “10001” in the second entry for the term “ne”, indicating that the input data being “ne” at state 2 may enable state 4.

Similarly, the state block 158 may be coupled to a one-hot encoder 168, which may be used to generate an address (e.g., the queue index) of a states RAM 178 (e.g., an indirection table) based on search results of the terms stored in the state block 158. The states RAM 178 may store the corresponding state vector “10001” in the first entry for the term “e@”, indicating that the input data being “e@” at state 3 may enable state 4.

The outputs (e.g., state vectors) of the states RAM 172, 174, 176, and 178 may be combined using an OR logic circuit 179 to determine the states that may be enabled in the following clock cycle. An active states register 180 may be used to store the current status (e.g., “1” represents “active”, “0” represents “not active”) of the states (e.g., state 0, state 1, state 2, state 3), and it may be updated every clock cycle. As mentioned above, bit 0 of a state vector is always high if it corresponds to the starting state of the NFA 120; accordingly, state 0 is always enabled for every clock cycle. The output of each states RAM may be confirmed by checking whether the state (e.g., state 0, state 1, state 2, state 3) it comes from is currently enabled using the active states register 180. For example, the output of each states RAM (e.g., states RAM 172, 174, 176, 178) and the status of the corresponding state (e.g., state 0, state 1, state 2, state 3) may be input into a respective AND logic circuit (e.g., block 182, block 184, block 186, block 188) before entering the OR logic circuit 179. For example, if state 2 is not enabled, then the status stored in the active states register 180 for state 2 is “0”, which may be input into the AND block 186 with the output from the states RAM 176, causing the output from the states RAM 176 not being considered in the OR logic circuit 179 for the states to be enabled in the following clock cycle. Accordingly, the input data being ‘nn’ may not cause invalid states to be enabled in the following clock cycle. All confirmed states RAM outputs may be combined (e.g., “OR”ed) and stored in the active states register 180, and the clock cycle continues. The bit associated with the end state (e.g., state 4) in the active states register 180 is the match found bit, as when the end state is enabled, the match is complete. The NFA accelerator core 150 may be configurable (e.g., via a configuration interface not shown in FIG. 5) so that the terms stored in the state blocks (e.g., the state blocks 152, 154, 156, 158) and corresponding state vectors stored in the states RAM (e.g., the states RAMs 172, 174, 176, 178) may be modified or updated during runtime, thereby allowing runtime reconfigurability.

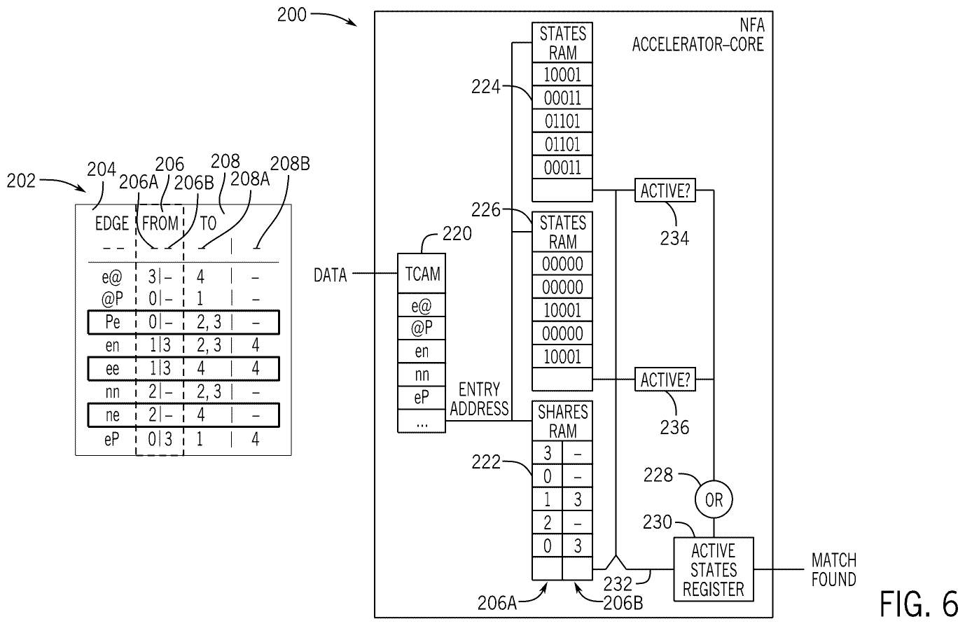

FIG. 6 is a flow diagram for a process to use TCAM in another embodiment of a NFA accelerator core 200 to search a regular expression (e.g., “Pen*e”) in input data. The NFA accelerator core 200 may reduce the depth of the TCAM by only storing unique edges in the TCAM, thereby lowering resource utilization and/or increasing maximum frequency. In addition, the NFA accelerator core 200 may include a priority logic circuit in the TCAM to provide mapping address directly (e.g., without using one-hot encoders) corresponding to the priority of the matched terms (e.g., the highest match). All edges of the NFA 120 may be collected and combined such that only unique edges are included in a table 202. The table 202 includes all unique edges of the NFA 120 and corresponding starting states and next states that may be activated in the next clock cycle corresponding to the starting states. For instance, the table 202 may include a column 204 to include all unique edges of the NFA 120, a column 206 to include corresponding starting states, and a column 208 to include corresponding next states. In the illustrated embodiment of FIG. 6, edges may be combined so that the column 204 only includes unique edges of the NFA 120, and the maximum number of edges that may be combined is 2. Accordingly, two states RAMs (e.g., a states RAM 224, a states RAM 226) may be used to store next states, which may be activated in the next clock cycle corresponding to starting states stored in two columns in a shares RAM (e.g., a shares RAM 222). For example, the column 206 may include a list 206A to include first starting states of the corresponding edges in the column 204, and a list 206B to include second starting states (“-” in list 206B representing “not available”) of the corresponding edges in the column 204. The column 208 may include a list 208A to include next states corresponding to the first starting states in the list 206A, and a list 208B to include next states corresponding to the second starting states in the list 206B (“−” in list 208B representing “not available”). For example, the edge labelled “e@” may start from state 3 and end at state 4; the edge labelled “@P” may start at state 0 and end at state 1; the edge labelled “Pe” may start at state 0 and end at state 2 and state 3; the edge labelled “en” may start from a first starting state at state 1 and end at state 2 and state 3, and a second starting state at state 3 and end at state 4; the edge labelled “ee” may start from a first starting state at state 1 and end at state 4, or a second starting state at state 3 and end at state 4; the edge labelled “nn” may start at state 2 and end at state 2 and state 3; the edge labelled “ne” may start at state 2 and end at state 4; and the edge labelled “eP” may start at a first starting state at state 0 and end at state 1, or a second starting state at state 3 and end at state 4. The edge labelled “eP” is not included in the NFA 120 illustrated in FIG. 4 but is included in the table 202. This is because the term “eP” may match both “@P” and “e@”, then an input of “eP” would match both edges. Therefore, a pseudo edge labeled “eP” may be used with combined results from the outputs of both “@P” and “e@”. Since the TCAM returns the address of the highest matching entry, then an input of “eP” would return “eP” not “e@” nor “@P”. Similarly, an input of “en” would match both “en” and “e@” hence the output of “e@” is included in “en” and the edges are reordered in the table 202.

In some embodiments, the NFA accelerator core 200 may include a TCAM table 220 to store the edges stored in the column 204 of the table 202. The NFA accelerator core 200 may include the shares RAM table (e.g., an indirection table) 222 to store all starting states stored in the column 206 of the table 202, with the first column storing the list 206A and the second column storing the list 206B. The NFA accelerator core 200 may include the states RAM table (e.g., an indirection table) 224 to store state vectors corresponding to the next states in the list 208A of the table 202. The NFA accelerator core 200 may include the states RAM table (e.g., an indirection table) 226 to store state vectors corresponding to the next states in the list 208B of the table 202. A parameter, Share_limit, may be used to define the maximum number of different states in the NFA 120 that may have an edge labelled the same. In other words, the parameter Share_limit defines the maximum number of starting states of an edge. In the illustrated embodiment of FIG. 4, the Share_limit of the NFA 120 is 2, which means two columns may be included in the shares RAM table 222 and two states RAM tables (e.g., the states RAM 222, the states RAM 224) may be used to store the state vectors. In other embodiments, the Share_limit of the NFA 120 may have different values (e.g., 3, 4, 5 . . . ), which correspond to different values (e.g., 3, 4, 5 . . . ) of the maximum number of different states in the NFA 120 that may have an edge labelled the same. Accordingly, the TCAM table 220, the shares RAM 222, the states RAM 224, and the states RAM 226 may store the edges and corresponding starting states and next states stored in the table 202. In the embodiment illustrated in FIG. 6, only some of the starting states combinations are included in the shares RAM table 220, and all tables (e.g., the TCAM table 220, the shares RAM 222, the states RAM 224, the states RAM 226) may have the same depth. For example, the circled terms “Pe”, “ee”, and “ne” in the column 204 are not included in the shares RAM table 220. In other embodiments, all starting states combinations may be included in the shares RAM table 220.

In the illustrated embodiment of FIG. 6, the TCAM table 220 may include a priority logic circuit to directly (e.g., without using an one-hot encoder) provide a mapping address (e.g., the shares RAM 222, the states RAM 224, the states RAM 226) corresponding to the priority of the matched terms (e.g., the highest match). For example, if the term “e@” is matched with the input data, the TCAM table 220 may output “00001”, corresponding to the first entry of the shares RAM 222, which stores the starting states of the edge “e@” as listed in the column 206, the first entry of the states RAM 224, which stores a state vector “10001” indicating the corresponding next states of the edge “e@” listed in the list 208A, and the first entry of the states RAM 226, which stores a state vector “00000” indicating no corresponding next state of the edge “e@” listed in the list 208B (“−” representing “not available” in the list 206B and the list 208B). The outputs of the states RAM 224 and 226 may be combined using an OR logic circuit 228 to determine the states that may be enabled in the following clock cycle. An active states register 230 may be used to store the current status (e.g., “1” represents “active”, “0” represents “not active”) of the states (e.g., state 0, state 1, state 2, state 3), and it may be updated every clock cycle. The output of the states RAM 224 and the output of the states RAM 226 may be selected based on the output of the shares RAM 222 and the currently enabled state stored in the active states register 230. For example, the output of the shares RAM 222 may be compared with the currently enabled state stored in the active states register 230 (e.g., via an AND block 232) to determine the currently enabled starting state. The output of the states RAM 224 and the currently enabled starting state output from the AND block 232 may be input into an AND logic circuit block 234 before entering the OR logic circuit 228. The output of the states RAM 226 and the currently enabled starting state output from the AND block 232 may be input into an AND logic circuit block 236 before entering the OR logic circuit 228. For example, in the above example for the edge “e@”, the output of the shares RAM 222 may include state 3 (with “-” representing “not available”). If state 3 is not currently enabled, then the status stored in the active states register 230 for state 3 is “0”, which may be input into the AND block 232 together with the output from the shares RAM 222. Then the output of the AND block 232 may be input into the block 234 with the output from the states RAM 224, causing the state vector “10001” not being considered in the OR logic circuit 228 for the states to be enabled in the following clock cycle. The output state vector “00000” from the states RAM 226 may also not be considered in the OR logic circuit 228 for the states to be enabled in the following clock cycle since the second column of the first entry of the shares RAM 222 include “-” representing “not available”, means no second starting state. In addition, bit 0 of the state vector “00000” having a value of “0” may indicate the corresponding starting state not available.

In another example, if the term “en” is matched with the input data, the TCAM 220 table may output “00100” corresponding to the third entry of the shares RAM 222, the states RAM 224, and the states RAM 226. The shares RAM 222 stores the starting states of the edge “en” as listed in the column 206. The third entry of the states RAM 224 stores a state vector “01101” indicating the corresponding next states of the edge “en” listed in the list 208A. The third entry of the states RAM 226 stores a state vector “10001” indicating the corresponding next state of the edge “en” listed in the list 208B. The output of the shares RAM 222 may include state 1 and state 3. If state 1 is currently enabled, then the status stored in the active states register 230 for state 1 is “1”, which may be input together with the output from the shares RAM 222 into the AND block 232 outputting a value “1”. The output of the AND block 232 may be input into the block 234 together with the output from the states RAM 224 causing the state vector “10001” to be considered in the OR logic circuit 228 for the states to be enabled in the following clock cycle. If state 3 is not currently enabled, then the status stored in the active states register 230 for state 3 is “0”, which may be input together with the output from the shares RAM 222 into the AND block 232 outputting a value “0”. Then, the output of the AND block 232 may be input into the block 236 with the output from the states RAM 226, causing the state vector “10001” not being considered in the OR logic circuit 228 for the states to be enabled in the following clock cycle.

All confirmed states RAM outputs may be combined (e.g., “OR”ed) and stored in the active states register 230, and the clock cycle continues. The bit associated with the end state (e.g., state 4) in the active states register 230 is the match found bit, as when the end state is enabled, the match is complete. The NFA accelerator core 200 may be configurable (e.g., via a configuration interface not shown in FIG. 6) so that the terms stored in the TCAM 220 and the corresponding state vectors stored in the states RAM (e.g., the shares RAM 222, the states RAMs 224, 226) may be modified or updated during runtime, thereby allowing runtime reconfigurability, such as using a partial reconfiguration of the programmable logic device.

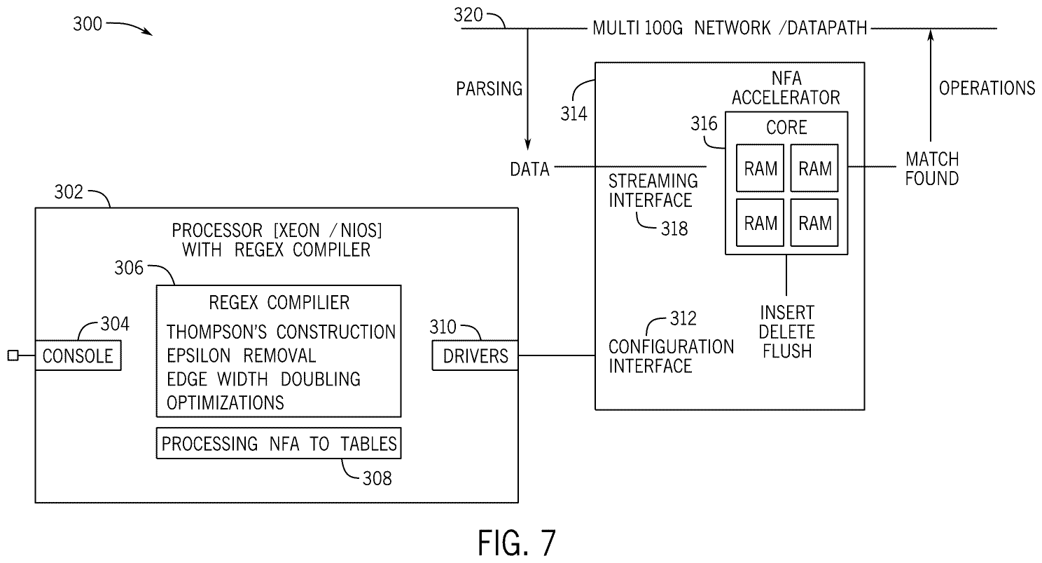

FIG. 7 is a block diagram showing an implementation of a regular expression engine 300. The regular expression engine 300 may include a processor 302 (e.g., of host 18), which may implement a console 304 to receive input. The processor 302 may include a software driver library for converting a given regular expression to an encoding compatible with the accelerator design, and the software driver library may provide viability of the design in different circumstances. The software driver library may include a RegEx compiler 306 to transform a regular expression, to which a user wishes to match against, to an efficient NFA. For example, the RegEx compiler 306 may be configured to parse the regular expression into a parsed form (e.g., an expression tree), and the parser may support the standard features of POSIX extended regular expressions. The RegEx compiler 306 may apply Thompson's construction to convert this parsed form to an NFA, which may contain epsilon transitions. The hardware may not support the epsilon transitions natively, therefore, the RegEx compiler 306 may be configured to perform epsilon transition elimination. The RegEx compiler 306 may also apply standard algorithms to obtain optimizations (e.g., “best effort” NFA minimization). The RegEx compiler 306 may also perform edge-width doubling using Yamagaki's Algorithm (e.g., the NFA 120) and/or other algorithms, as illustrated in FIG. 4. Doubling edge widths may increase throughput massively, at the expense of additional transitions/states.

The software driver library may include a component 308 to convert the NFA (e.g., the NFA 120) output from the RegEx compiler 306 into the hardware table format of an NFA accelerator 314 of the regular expression engine 300 (e.g., for implementation in the programmable logic device). The component 308 may map the states and transitions of the NFA to entries in the hardware tables (e.g., the state blocks 152, 154, 156, 158, the TCAM table 220, the states RAMs, the shares RAM), as well as meeting all the requirements imposed by the hardware design, including the specifics of edge encoding and de-duplication/prioritization of “Don't Care” bits on edges, as described above with reference to FIGS. 5 and 6.

The processor 302 may include drivers 310 coupled to a configuration interface 312 of the NFA accelerator 314. The hardware table format of the NFA may be uploaded to an NFA accelerator core 316 (e.g., the NFA accelerator core 150, the NFA accelerator core 200) of the NFA accelerator 314 via the configuration interface 312. The NFA accelerator 314 may be part of the programmable logic device/integrated circuit device 10. The NFA accelerator core 316 may include TCAM tables (e.g., the state blocks 152, 154, 156, 158, the TCAM table 220) to store edges and RAM devices (e.g., states RAMs 172, 174, 176, 178, 224, 226, shares RAM 222) to store states, as described above with reference to FIG. 5 and FIG. 6. The configuration interface 312 may enable management of (e.g., via inserting, deleting, flushing) the entries of the hardware tables of the NFA accelerator core 316. For example, the terms stored in the state blocks (e.g., the state blocks 152, 154, 156, 158) and corresponding state vectors stored in the states RAM (e.g., the states RAMs 172, 174, 176, 178) of the NFA accelerator core 316 may be modified or updated during runtime, thereby allowing runtime reconfigurability. In some embodiments, multiple (e.g., two, three, four . . . ) regular expressions may be matched simultaneously by the regular expression engine 300. For example, the bit of the state vector associated with the end state of a regular expression is the match found bit for the regular expression, as when the end state is enabled (e.g., the bit has a value of “1”), the match is complete for the regular expression. Accordingly, multiple bits (e.g., two, three, four . . . ) of a state vector may be mapped to respective end states of corresponding regular expressions and may be checked simultaneously, and when the respective end states are enabled (e.g., in the same clock cycle or in different clock cycles), the matches are complete for the corresponding regular expressions (e.g., in the same clock cycle or in different clock cycles).

The NFA accelerator 314 may include a streaming interface 318 to receive input data from a data path 320 (e.g., via multi 100G network). The input data may be sent to the NFA accelerator core 316, which may accelerate the regular expression matching in the input data. The NFA accelerator 314 may couple the match found by the NFA accelerator core 316 back to the data path 320.

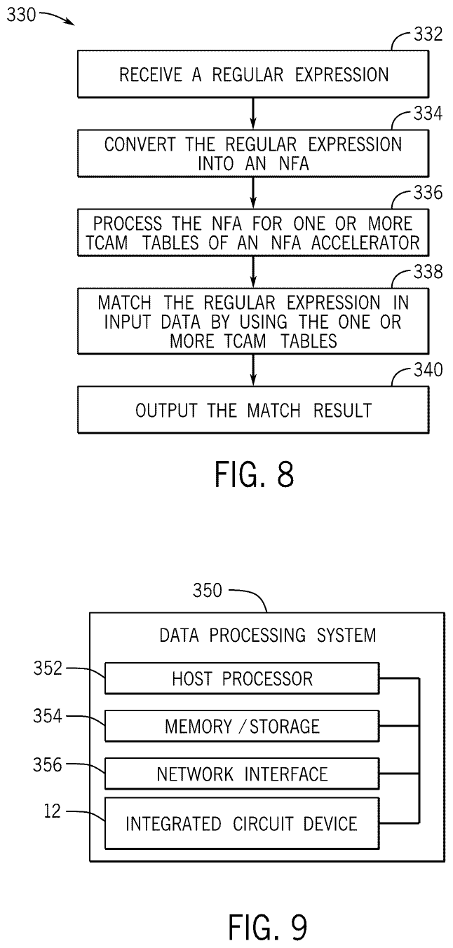

FIG. 8 is a flow chart showing a method 330 for matching a regular expression. At block 332, a regular expression is received by a processor (e.g., the processor 302), which may include a compiler (e.g., the RegEx compiler 306) to convert the regular expression into an NFA (e.g., the NFA 120) at block 334. The processor processes the NFA (e.g., via the component 308) to table format for tables (e.g., the state blocks 152, 154, 156, 158, the TCAM table 220) of an NFA accelerator (e.g., the NFA accelerator 314) at block 336. The NFA accelerator then attempts to match the regular expression in input data received from a data path using the one or more TCAM tables (e.g., as illustrated in FIGS. 5 and 6) at block 338. When a match is found in the input data, the match result is output at block 340.

Bearing the foregoing in mind, the integrated circuit device 12 may be a component included in a data processing system, such as a data processing system 350, shown in FIG. 9. The data processing system 350 may include the integrated circuit device 12 (e.g., a programmable logic device), a host processor 352 (e.g., a processor), memory and/or storage circuitry 354, and a network interface 356. The data processing system 350 may include more or fewer components (e.g., electronic display, designer interface structures, ASICs). Moreover, any of the circuit components depicted in FIG. 9 may include integrated circuits (e.g., integrated circuit device 12). The host processor 352 may include any of the foregoing processors that may manage a data processing request for the data processing system 350 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 354 may include random access memory (RAM), read-only memory (ROM), one or more hard drives, flash memory, or the like. The memory and/or storage circuitry 354 may hold data to be processed by the data processing system 350. In some cases, the memory and/or storage circuitry 354 may also store configuration programs (bit streams) for programming the integrated circuit device 12. The network interface 356 may allow the data processing system 350 to communicate with other electronic devices. The data processing system 350 may include several different packages or may be contained within a single package on a single package substrate. For example, components of the data processing system 350 may be located on several different packages at one location (e.g., a data center) or multiple locations. For instance, components of the data processing system 350 may be located in separate geographic locations or areas, such as cities, states, or countries.

In one example, the data processing system 350 may be part of a data center that processes a variety of different requests. For instance, the data processing system 350 may receive a data processing request via the network interface 356 to perform encryption, decryption, machine learning, video processing, voice recognition, image recognition, data compression, database search ranking, bioinformatics, network security pattern identification, spatial navigation, digital signal processing, or some other specialized task.

Accordingly, the implementation herein is directed to systems and methods using TCAM tables in an NFA accelerator to achieve high throughput regular expression matching, improved scalability, improved resource utilization, and runtime and compile time reconfigurability, while remaining easy-to-deploy (no reliance on specialized hardware) thereby reducing customer barrier-to-entry. The architecture is programmable at runtime due to its dependency on TCAM for its configuration data. Moreover, FPGA gates may be used in the NFA accelerator and may be replaced at runtime using partial reconfiguration to allow limitations in the number of indirection tables and the capacities of the TCAMs to be adjusted at runtime. Accordingly, the FPGA based solution can be hardened in ASIC or eASIC and retain performance and flexibility within some limits. Furthermore, when implemented in FPGA, the limits to flexibility may be overcome through partial reconfiguration. It should be noted that, in the illustrated embodiments above, the NFA accelerator is primarily described in the context of regular expression matching. In other embodiments, however, the NFA accelerator may be used for other applications.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. A nondeterministic finite automata (NFA) accelerator comprising:
one or more content-addressable memory (CAM) tables that comprise one or more terms corresponding to respective edge labels of an NFA of a regular expression;
one or more states RAM tables that comprise a respective state vector for each of the one or more terms, wherein the respective state vectors indicate respective states of the NFA to be enabled in a next clock cycle; and
an active states register configured to store state statuses for the NFA.

EXAMPLE EMBODIMENT 2. The NFA accelerator of example embodiment 1, wherein the one or more CAM tables comprise one or more ternary content-addressable memory (TCAM) tables.

EXAMPLE EMBODIMENT 3. The NFA accelerator of example embodiment 2, wherein the one or more terms comprise a term corresponding to a pseudo edge of the NFA.

EXAMPLE EMBODIMENT 4. The NFA accelerator of example embodiment 1, wherein the NFA accelerator is configured to search the one or more CAM tables in one clock cycle.

EXAMPLE EMBODIMENT 5. The NFA accelerator of example embodiment 1, wherein each of the one or more CAM tables corresponds to a respective state of the NFA and stores a respective set of terms of the one or more terms corresponding to respective set of edge labels of the respective state, and wherein a respective states RAM table of the one or more states RAM tables stores respective state vectors for the respective set of terms.

EXAMPLE EMBODIMENT 6. The NFA accelerator of example embodiment 5, wherein each of the one or more CAM tables is coupled to a respective one-hot encoder to generate respective addresses of the respective state vectors stored in the respective states RAM table.

EXAMPLE EMBODIMENT 7. The NFA accelerator of example embodiment 1, comprising a configuration interface configured to modify at least one of the one or more CAM tables and the one or more states RAM table during a runtime period of the NFA accelerator.

EXAMPLE EMBODIMENT 8. A nondeterministic finite automata (NFA) accelerator comprising:
a content-addressable memory (CAM) table that comprises one or more terms corresponding to respective edge labels of an NFA of a regular expression;
a shares RAM table that comprises a first set of starting states and a second set of starting states for the one or more terms;
a first states RAM table that comprises a first set of state vectors corresponding to the first set of starting states;
a second states RAM table that comprises a second set of state vectors corresponding to the second set of starting states; and
an active states register configured to store state statuses for the NFA.

EXAMPLE EMBODIMENT 9. The NFA accelerator of example embodiment 8, wherein the CAM table comprises a ternary content-addressable memory (TCAM) table.

EXAMPLE EMBODIMENT 10. The NFA accelerator of example embodiment 9, wherein the one or more terms comprise a term corresponding to a pseudo edge of the NFA.

EXAMPLE EMBODIMENT 11. The NFA accelerator of example embodiment 8, wherein the NFA accelerator is configured to search the CAM table in one clock cycle.

EXAMPLE EMBODIMENT 12. The NFA accelerator of example embodiment 8, comprising an AND logic circuit to determine states to be enabled in a next clock cycle based on at least the state statuses stored in the active states register.

EXAMPLE EMBODIMENT 13. The NFA accelerator of example embodiment 8, comprising a configuration interface configured to modify at least one of the CAM table, the shares RAM table, the first states RAM table, and the second states RAM table during a runtime period of the NFA accelerator.

EXAMPLE EMBODIMENT 14. A method comprising:
receiving, via processing circuitry, a regular expression;
converting, via the processing circuitry, the regular expression into a nondeterministic finite automata (NFA);
processing, via the processing circuitry, the NFA for one or more content-addressable memory (CAM) tables of an NFA accelerator;
matching, via the NFA accelerator, the regular expression in input data by using the one or more CAM tables; and
outputting, via the NFA accelerator, a match result of the regular expression.

EXAMPLE EMBODIMENT 15. The method of example embodiment 14, wherein converting the regular expression into the NFA comprises using an algorithm for edge-width doubling.

EXAMPLE EMBODIMENT 16. The method of example embodiment 15, wherein each edge of the NFA comprises a plurality of characters.

EXAMPLE EMBODIMENT 17. The method of example embodiment 14, wherein the one or more CAM tables comprise one or more ternary content-addressable memory (TCAM) tables.

EXAMPLE EMBODIMENT 18. The method of example embodiment 14, wherein the NFA accelerator is configured to search the one or more CAM tables in one clock cycle.

EXAMPLE EMBODIMENT 19. The method of example embodiment 14, comprising configuring the NFA accelerator via a configuration interface of the NFA accelerator during a runtime period of the NFA accelerator.

EXAMPLE EMBODIMENT 20. The method of example embodiment 19, wherein configuring the NFA accelerator comprises modifying the one or more CAM tables during the runtime period of the NFA accelerator.

What is claimed is:

1. A nondeterministic finite automata (NFA) accelerator comprising:
one or more content-addressable memory (CAM) tables that comprise one or more terms corresponding to respective edge labels of an NFA of a regular expression;
one or more states RAM tables that comprise a respective state vector for each of the one or more terms, wherein the respective state vectors indicate respective states of the NFA to be enabled in a next clock cycle; and
an active states register configured to store state statuses for the NFA.

2. The NFA accelerator of claim 1, wherein the one or more CAM tables comprise one or more ternary content-addressable memory (TCAM) tables.

3. The NFA accelerator of claim 2, wherein the one or more terms comprise a term corresponding to a pseudo edge of the NFA.

4. The NFA accelerator of claim 1, wherein the NFA accelerator is configured to search the one or more CAM tables in one clock cycle.

5. The NFA accelerator of claim 1, wherein each of the one or more CAM tables corresponds to a respective state of the NFA and stores a respective set of terms of the one or more terms corresponding to respective set of edge labels of the respective state, and wherein a respective states RAM table of the one or more states RAM tables stores respective state vectors for the respective set of terms.

6. The NFA accelerator of claim 5, wherein each of the one or more CAM tables is coupled to a respective one-hot encoder to generate respective addresses of the respective state vectors stored in the respective states RAM table.

7. The NFA accelerator of claim 1, comprising a configuration interface configured to modify at least one of the one or more CAM tables and the one or more states RAM table during a runtime period of the NFA accelerator.

8. A nondeterministic finite automata (NFA) accelerator comprising:
a content-addressable memory (CAM) table that comprises one or more terms corresponding to respective edge labels of an NFA of a regular expression;
a shares RAM table that comprises a first set of starting states and a second set of starting states for the one or more terms;
a first states RAM table that comprises a first set of state vectors corresponding to the first set of starting states;
a second states RAM table that comprises a second set of state vectors corresponding to the second set of starting states; and
an active states register configured to store state statuses for the NFA.

9. The NFA accelerator of claim 8, wherein the CAM table comprises a ternary content-addressable memory (TCAM) table.

10. The NFA accelerator of claim 9, wherein the one or more terms comprise a term corresponding to a pseudo edge of the NFA.

11. The NFA accelerator of claim 8, wherein the NFA accelerator is configured to search the CAM table in one clock cycle.

12. The NFA accelerator of claim 8, comprising an AND logic circuit to determine states to be enabled in a next clock cycle based on at least the state statuses stored in the active states register.

13. The NFA accelerator of claim 8, comprising a configuration interface configured to modify at least one of the CAM table, the shares RAM table, the first states RAM table, and the second states RAM table during a runtime period of the NFA accelerator.

14. A method comprising:
receiving, via processing circuitry, a regular expression;
converting, via the processing circuitry, the regular expression into a nondeterministic finite automata (NFA);
processing, via the processing circuitry, the NFA for one or more content-addressable memory (CAM) tables of an NFA accelerator;
matching, via the NFA accelerator, the regular expression in input data by using the one or more CAM tables; and
outputting, via the NFA accelerator, a match result of the regular expression.

15. The method of claim 14, wherein converting the regular expression into the NFA comprises using an algorithm for edge-width doubling.

16. The method of claim 15, wherein each edge of the NFA comprises a plurality of characters.

17. The method of claim 14, wherein the one or more CAM tables comprise one or more ternary content-addressable memory (TCAM) tables.

18. The method of claim 14, wherein the NFA accelerator is configured to search the one or more CAM tables in one clock cycle.

19. The method of claim 14, comprising configuring the NFA accelerator via a configuration interface of the NFA accelerator during a runtime period of the NFA accelerator.

20. The method of claim 19, wherein configuring the NFA accelerator comprises modifying the one or more CAM tables during the runtime period of the NFA accelerator.
